(19) United States
(12) Patent Application Publication
(10) Pub. No.: US 2015/0228379 A1
(43) Pub. Date: Aug. 13, 2015

(54) SUPERCONDUCTING BODY AND METHOD OF FORMING THE SAME

(71) Applicants: SUNAM CO., LTD., Anseong-si, Gyeonggi-do (KR); SNU R&DB FOUNDATION, Seoul (KR)

(72) Inventors: Sang-Im Yoo, Seoul (KR); Jung-Woo Lee, Seoul (KR); Soon Mi Choi, Seoul (KR); Seung Hyun Moon, Seongnam-si (KR); Hun Ju Lee, Yongin-si (KR); Jae Hun Lee, Gimpo-si (KR)

(21) Appl. No.: 14/420,113

(22) PCT Filed: Oct. 8, 2012
(86) PCT No.: PCT/KR2012/008132

§ 371 Date: Feb. 6, 2015

(30) Foreign Application Priority Data
Aug. 6, 2012 (KR) 10-2012-0085768

(51) Int. Cl. H01B 12/06; H01L 39/12; H01L 39/24; H01B 1/08; H01B 13/00

(52) U.S. Cl. CPC H01B 12/06; H01B 1/08; H01B 13/0016; H01L 39/2419; H01L 39/126

(57) ABSTRACT

Provided is a method of forming a superconducting body. The method includes providing amorphous rare-earth-copper-barium oxide and performing a heat treatment on the amorphous rare-earth-copper-barium oxide to form a superconductor containing distributed rare-earth oxide grains.

### TECHNICAL FIELD

The present invention relates to a superconducting body and method of forming the same.

### BACKGROUND ART

A superconductor allows a large amount of currents to flow because electrical resistance of the superconductor disappears at a low temperature below its superconducting transition temperature. In recent years, researches have been intensively focused on the second-generation high-temperature superconducting wire (coated conductor) in which a superconducting film is formed on a biaxially textured thin buffer layer on a metal substrate. The second-generation coated conductor may have been applied to various fields of applications. For example, a wire using the second-generation coated conductor exhibits more excellent current transfer capacity per unit area than a general metal wire. The wire using the second-generation coated conductor can reduce power loss of a power device. It can also be used in magnetic fields such as a magnetic resonance imaging (MRI), a superconducting magnetic levitation train, and a superconducting electromagnetic propulsion ship.

### DISCLOSURE

### Technical Problem

Embodiments of the inventive concept provide a high quality superconducting body and a method of forming the same.

### Technical Solution

According to an aspect of the inventive concept, a method of forming a superconducting body is provided. The method may include providing rare-earth element-copper-barium oxide including a rare-earth element, barium, and copper; and performing a heat treatment on the rare-earth element-copper-barium oxide to form a superconductor containing grains of rare-earth oxide distributed therein. Performing the heat treatment on the rare-earth element-copper-barium oxide may include a first heat treatment step in which a temperature increases such that the rare-earth element-copper-barium oxide has a liquid phase containing the rare-earth oxide; and a second heat treatment step in which a temperature and/or an oxygen pressure are changed from that of the first heat treatment step to form a crystalline rare-earth element-copper-barium oxide.

According to another aspect of the inventive concept, rare-earth element-barium-copper oxide is provided. The rare-earth-barium-copper oxide may include grains of a rare-earth oxide and grains of barium-cooper oxide which are distributed therein and have a crystalline structure.

In an exemplary embodiment, the rare-earth-barium-copper oxide may further include grains of copper oxide distributed and contained in the crystalline rare-earth element-barium-copper oxide.

In an exemplary embodiment, each of the grains of rare-earth oxide may have an elongated shape.

### Advantageous Effects

As described so far, a superconductor having an excellent crystallinity can be formed by means of a higher-speed process. In addition, grains of the rare-earth element functioning as pinning centers in the superconductor can be easily formed.

### DESCRIPTION OF DRAWINGS

FIG. 1 is a stability phase diagram of GdBCO.

FIGS. 2 to 6 are cross-sectional views illustrating a method of forming a superconducting body according to embodiments of the inventive concept.

FIGS. 7 to 9 are TEM images of an epitaxial superconducting body formed according to embodiments of the inventive concept.

FIG. 10 is an XRD pattern of an epitaxial superconducting body formed according to embodiments of the inventive concept.

FIG. 11 is a block diagram of an apparatus for forming a superconducting body according to the inventive concept.

FIG. 12 shows a cross section of a thin film deposition unit in an apparatus for forming a superconducting body according to the inventive concept.

FIG. 13 is a top plan view of a reel-to-reel device according to the inventive concept.

FIG. 14 schematically illustrates a heat treatment unit in an apparatus for forming a superconducting body according to the inventive concept.

### MODE FOR INVENTION

The inventive concept will now be described more fully hereinafter with reference to the accompanying drawings, in which preferred embodiments of the inventive concept are shown. However, the inventive concept may be embodied in many different forms and should not be construed as limited to the embodiments set forth herein. Rather, these embodiments are provided so that this disclosure will be thorough and complete, and will fully convey the scope of the inventive concept to those skilled in the art. Like numbers refer to like elements throughout.

In embodiments of the inventive concept described below, GdBCO will be explained as a superconductor. However, it will be understood by those skilled in the art that the superconductor is not limited thereto.

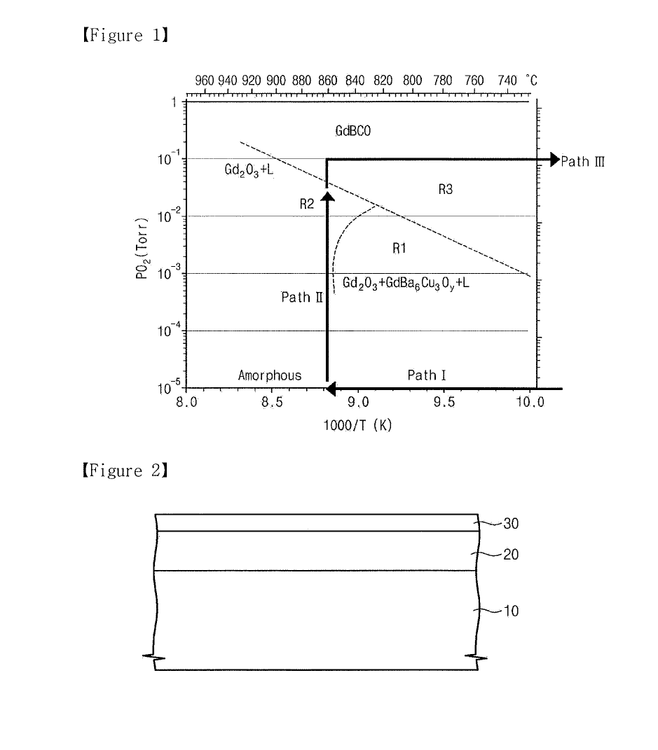

FIG. 1 is a stability phase diagram of GdBCO. A first region R1 may have a phase at an oxygen partial pressure less than about 10⁻² Torr and at a temperature less than about 850 degrees centigrade. A second region R2 may have a phase at an oxygen partial pressure less than about 10⁻¹ to 10⁻² Torr and a temperature less than about 850 degrees centigrade. A third region R3 may have a phase at a higher oxygen partial pressure and a lower temperature than those of the first region R1 and the second region R2.

It will be understood that in the first region R1, Gd₂O₃, GdBa₆Cu₃O_{y}, and a liquid phase co-exist. The liquid phase contains barium (Ba), copper (Cu), and oxygen (O) as main components and gadolinium (Gd) dissolved therein. It will be understood that in the second region R2, Gd₂O₃ and a liquid phase co-exist. It will be understood that in the third region R3, GdBCO is thermodynamically stable.

FIGS. 2 to 6 are cross-sectional views illustrating a method of forming a superconducting body according to embodiments of the inventive concept. With reference to FIGS. 2 to 6, a method of forming a superconducting body according to the inventive concept will be described in brief.

Referring to FIG. 2, a substrate 10 is provided. The substrate 10 may have a biaxially aligned textured structure. The substrate 10 may be, for example, a metal substrate. The metal substrate may be a cubic metal such as a rolled and heat-treated nickel, a Ni-alloy (e.g., Ni—W, Ni—Cr, Ni—Cr—W, etc.), silver, a silver-alloy, and a Ni-silver composite. The substrate 10 may be a type of tape for a plate or line material.

An IBAD layer 20 may be formed on the substrate 10. The IBAD layer 20 may include a diffusion barrier layer (e.g., Al₂O₃), a seed layer (e.g., Y₂O₃), and an MgO layer which are sequentially stacked. The IBAD layer 20 is formed by an IBAD process. An epitaxially grown homoepi-MgO layer may be further formed on the MgO layer. A buffer layer 30 may be formed on the IBAD layer 20. The buffer layer 30 may include LaMnO₃, LaAlO₃, CeO₂ or SrTiO₃. The buffer layer 30 may be formed by a sputtering process. The IBAD layer 20 and the buffer layer 30 can prevent reaction of the substrate with the superconducting material thereon and transfer crystallinity of the biaxially aligned textured structure.

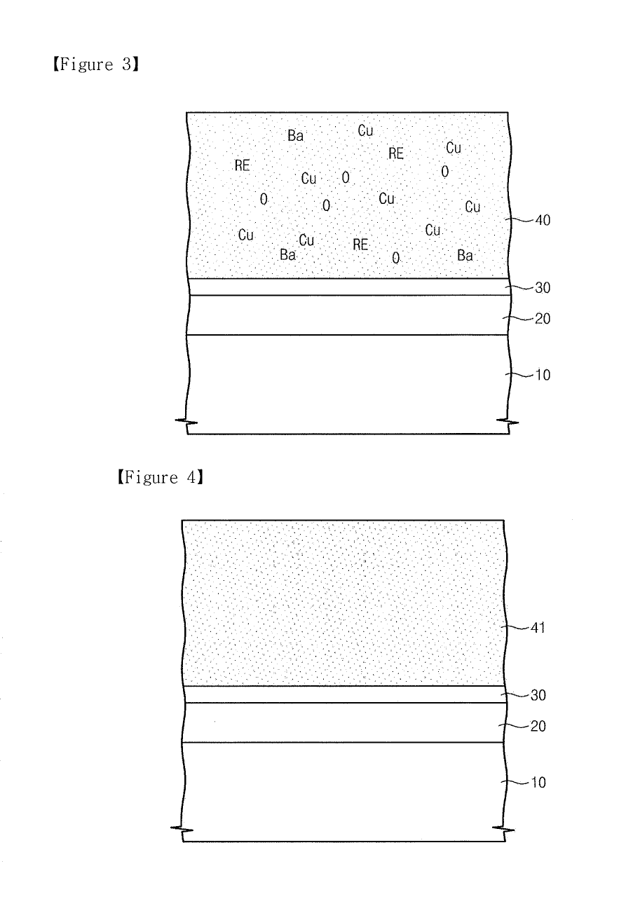

Referring to FIG. 3, a superconducting precursor film 40 is formed on the buffer layer 30. The superconducting precursor film 40 may include at least one (e.g., Gd) of a rare-earth element (RE), copper (Cu), and barium (Ba).

The superconducting precursor film 40 may be formed in various manners. The superconducting precursor film 40 may be formed by means of, for example, reactive co-evaporation, PLD, sputtering, CVD, metal organic deposition (MOD) or a sol-gel process. However, the formation of the superconducting precursor film 40 is not limited to the above manners.

For an example, the superconducting precursor film 40 may be formed by means of reactive co-evaporation. In the reactive co-evaporation, the metal vapors generated by irradiating an electron beam to copper (Cu) and barium (Ba) contained in a container may be provided onto the substrate to deposit the superconducting precursor film. It will be understood that the rare-earth elements (RE) may be yttrium-based (Y-based) elements, lanthanum-based (La-based) elements or combinations thereof. As well known, the La-based elements include La, Nd, Sm, Eu, Gd, Tb, Dy, Ho, Er, Tm, Yb, Lu, and so forth.

Another example may be the superconducting precursor film 40 formed by means of metal organic deposition (MOD). For example, RE-acetate, Ba-acetate, Cu-acetate are dissolved in an organic solvent and evaporation, distillation, re-dissolution, and refluxing processes are performed to prepare a metal precursor solution including at least one of the rare-earth elements, Cu, and Ba. The metal precursor solution is collated on the substrate.

Referring to FIG. 4, a first heat treatment is performed on the substrate 10 where the superconducting precursor film 40 is formed. The first heat treatment may be performed at an oxygen partial pressure of 10⁻³ Torr to 10⁻⁶ Torr. The oxygen partial pressure of the first heat treatment may be, for example, about 10⁻⁵ Torr. The temperature of the first heat treatment may increase to 700 to 800 degrees centigrade (e.g., about 860 degrees centigrade). The first heat treatment may be performed along a path I in FIG. 1. By the first heat treatment, an amorphous superconducting precursor film 40 may be formed on the substrate 10.

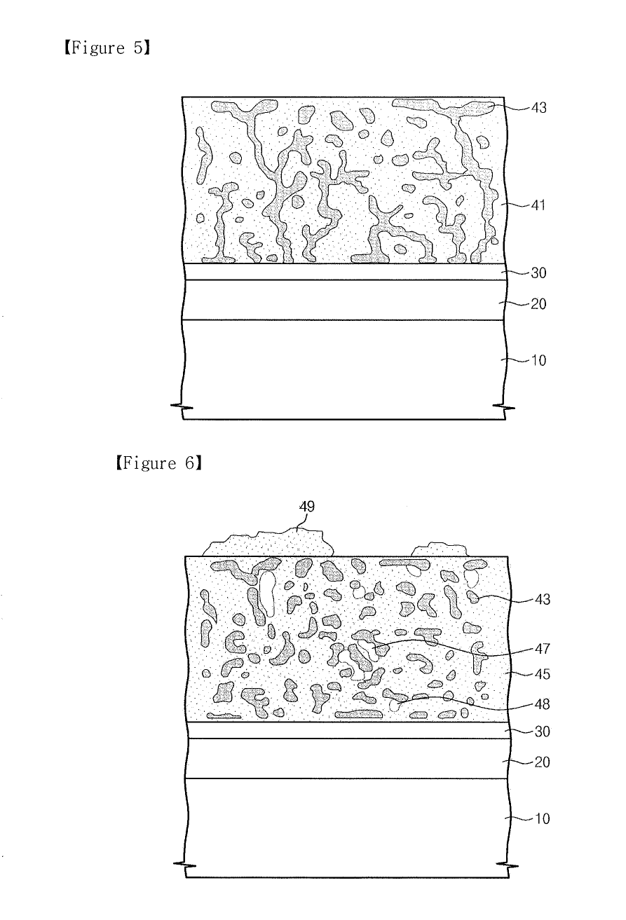

Referring to FIG. 5, a second heat treatment may be performed on the substrate 10 where the amorphous superconducting precursor film 40 is formed. The second heat treatment may be performed at a temperature of 700 to 1000 degrees centigrade (e.g., 860 degrees centigrade). The second heat treatment may be performed at a higher oxygen partial pressure than in the first heat treatment. During the second heat treatment, the oxygen partial pressure may increase, for example from 10⁻⁵ Torr to 10⁻² Torr˜10⁻¹ Torr (e.g., 30 mTorr). The second heat treatment may be performed along a path II in FIG. 1. By the second heat treatment, the amorphous superconducting precursor film 40 may be changed to a liquid-phase superconducting precursor body 41. Rare-earth oxide (e.g., Gd₂O₃) 43 may be formed in the liquid superconducting precursor body 41. The rare-earth oxide 43 may be dendritically grown from the buffer layer 30. That is, the liquid superconducting precursor body 41 containing the rare-earth oxide 43 may be formed by the second heat treatment performed along the path II.

Referring to FIG. 6, a third heat treatment is performed on the liquid superconducting precursor body 41 containing the rare-earth oxide 43. The third heat treatment may be a cooling process to decrease the temperature at an oxygen partial pressure of about 10⁻² Torr to several 10⁻¹ Torr. The cooling rate may be 1° C./hr or higher (about 5° C./hr). The third heat treatment may be performed along a path III in FIG. 1. By the third heat treatment, an epitaxial superconducting body 45 of rare-earth element-barium-copper oxide (hereinafter referred to as “RE-Ba-Cu oxide”) can be formed. The epitaxial superconducting body 45 of RE-Ba-Cu oxide may be generated from a liquid superconducting precursor body 41 while consuming the rare-earth element of the rare-earth oxide 43. Thus, an epitaxial superconducting body 45 having an excellent crystallinity can be formed with a very high-speed process.

In addition, the rare-earth oxide 43 decreases in size and is changed to elongated grains. The grains of the rare-earth oxide 43 may have a size less than 1 micrometer. Not only the grains of the rare-earth oxide 43 but also a liquid remnant 48 and grains of copper oxide 47 may be contained in the epitaxial superconducting body 45. Another liquid remnant 49 may remain on a top surface of the epitaxial superconducting body 45. The liquid remnants 48 and 49 may result from the liquid superconducting precursor body 41 that is not changed to the epitaxial superconducting body 45 and may be barium-copper oxide.

The grains 43 and 47 produced in the epitaxially grown superconducting body 45 may function as flux pinning centers of a superconductor. The grains of the rare-earth oxide 43 may have width ranging from tens of nanometers to 100 nanometers. Preferably, the grains of the rare-earth oxide 43 may have width less than 100 nanometers.

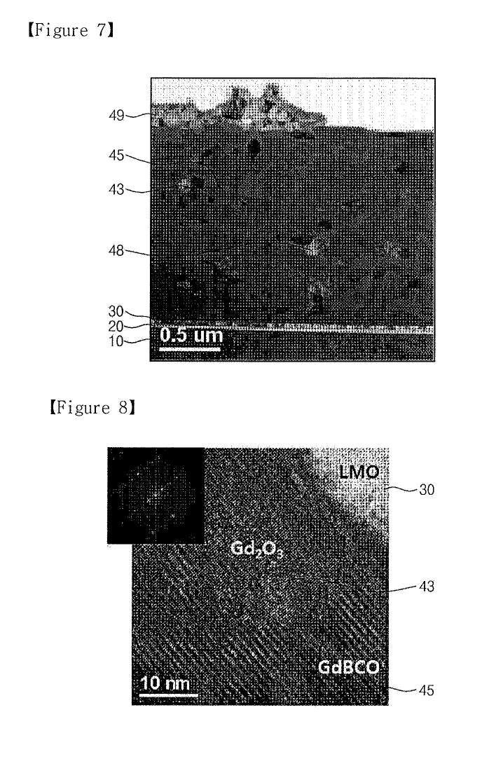

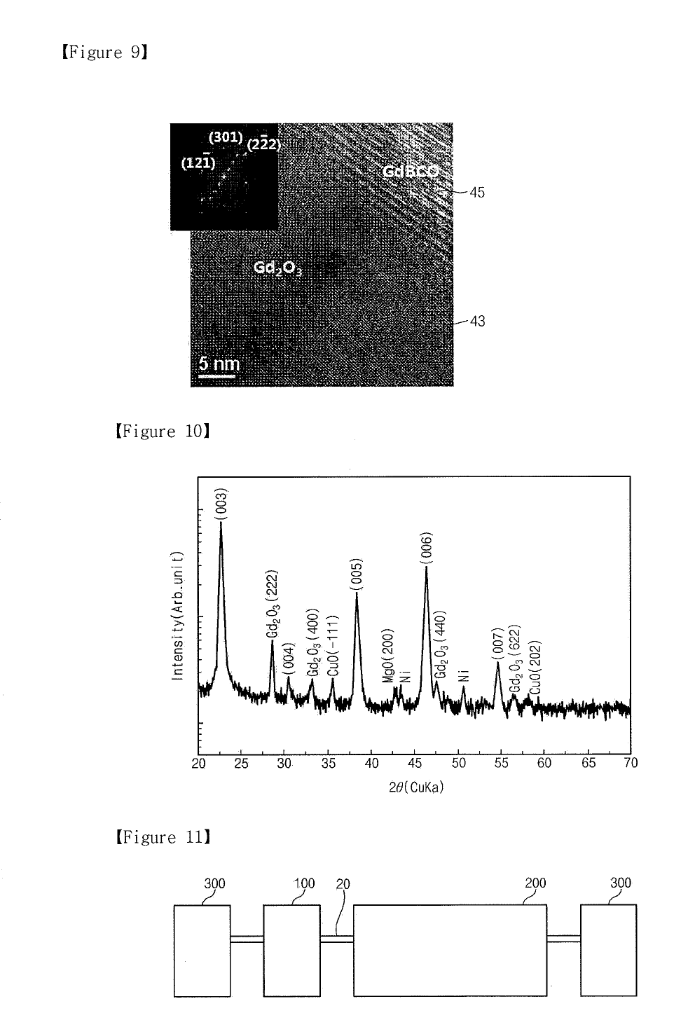

FIGS. 7 to 9 are TEM images of an epitaxial superconducting body 45 formed according to embodiments of the inventive concept. FIG. 7 shows an epitaxial superconducting body 45 on a substrate 10, grains of rare-earth oxide 43 contained in the epitaxial superconducting body 45, and liquid remnants 48 and 49. FIGS. 8 and 9 show an epitaxial superconducting body 45 on a substrate 10 and grains of rare-earth oxide (e.g., Gd₂O₃) 43. The grains of the rare-earth oxide 43 may have width of tens of nanometers.

FIG. 10 is an X-ray diffraction (XRD) pattern of an epitaxial superconducting body formed according to embodiments of the inventive concept. FIG. 10 shows an excellent crystallinity of an epitaxial superconducting body 45 of RE-Ba-Cu oxide.

A growth procedure of an epitaxial superconducting body according to the foregoing embodiments may be similar to that of liquid phase epitaxy (LPE). On the other hand, since FIG. 1 is a phase diagram of GdBCO, detailed oxygen partial pressure and heat treatment temperature may vary depending on the kind of rare-earth elements (RE).

While formation of a superconducting body has been described in the foregoing embodiments, the embodiments are not limited thereto. It will be apparent that heat treatments of the foregoing embodiments may be applied to a bulk superconductor. For example, amorphous RE-Ba-Cu oxide is prepared. The amorphous RE-Ba-Cu oxide may be changed to single-crystalline RE-Ba-Cu oxide through the above-described heat treatment. The single-crystalline RE-Ba-Cu oxide may include grains of rare-earth oxide and grains of barium-copper oxide that are distributed and contained therein.

With reference to FIGS. 11 to 14, an example of an apparatus for forming a superconducting body will be described. The apparatus described with reference to FIGS. 11 to 14 is an example according to the inventive concept for a superconducting wire, and the inventive concept is not limited thereto.

FIG. 11 is a block diagram of an apparatus for forming a superconducting body according to the inventive concept. Referring to FIG. 11, the apparatus for forming a superconducting body includes a thin film deposition unit 100 for forming a superconducting precursor film on a substrate, a heat treatment unit 200 for performing a heat treatment on the substrate including the superconducting precursor film formed in the thin film deposition unit 100, and a substrate feeding/collecting unit 300. A vacuum rod 20 may be further provided to maintain vacuum and allow a substrate to pass between the thin film deposition unit 100 and the heat treatment unit 200 and between the heat treatment unit 200 and the substrate feeding/collecting unit 300.

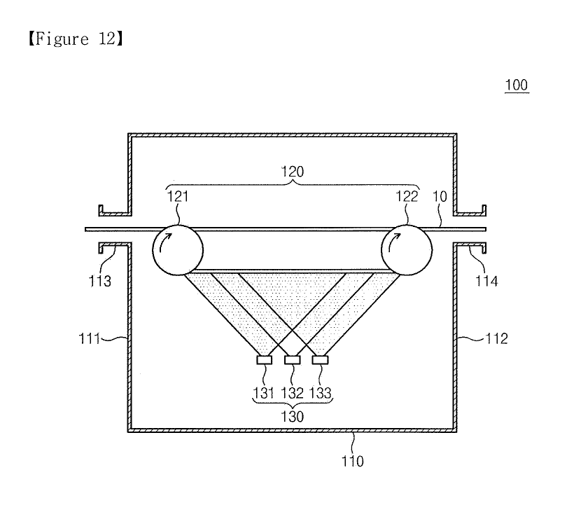

FIG. 12 shows a cross section of a thin film deposition unit in an apparatus for forming a superconducting body according to the inventive concept. Referring to FIGS. 11 and 12, a thin film deposition unit 100 may include a process chamber 110, a reel-to-reel device 120, and a deposition member 130. More specifically, the process chamber 110 provides a space in which a deposition process is performed to form a superconducting precursor film on a substrate 10. The process chamber 110 includes a first sidewall 111 and a second sidewall 112 that face each other. An introduction part 113 connected to the substrate feeding/collecting unit 300 is provided at the first sidewall 111, and a withdrawal part 114 connected to the heat treatment unit 200 is provided at the second sidewall 112. The substrate 10 is introduced to the process chamber 110 from the substrate feeding/collecting unit 300 through the introduction part 113 and introduced to the heat treatment unit 200 through the withdrawal part 114.

The deposition member 130 may be provided below the reel-to-reel device 120. Vapor of a superconducting material is supplied to a surface of the substrate 10. As an embodiment, the deposition member 130 may provide a superconducting precursor film onto the substrate 10 by means of co-evaporation. The deposition member 130 may include metal vapor sources 131, 132, and 133 that supply metal vapor by electron beam. The metal vapor sources 131, 132, and 133 may include a source for the rare-earth element, a source for barium (Ba), and a source for copper (Cu).

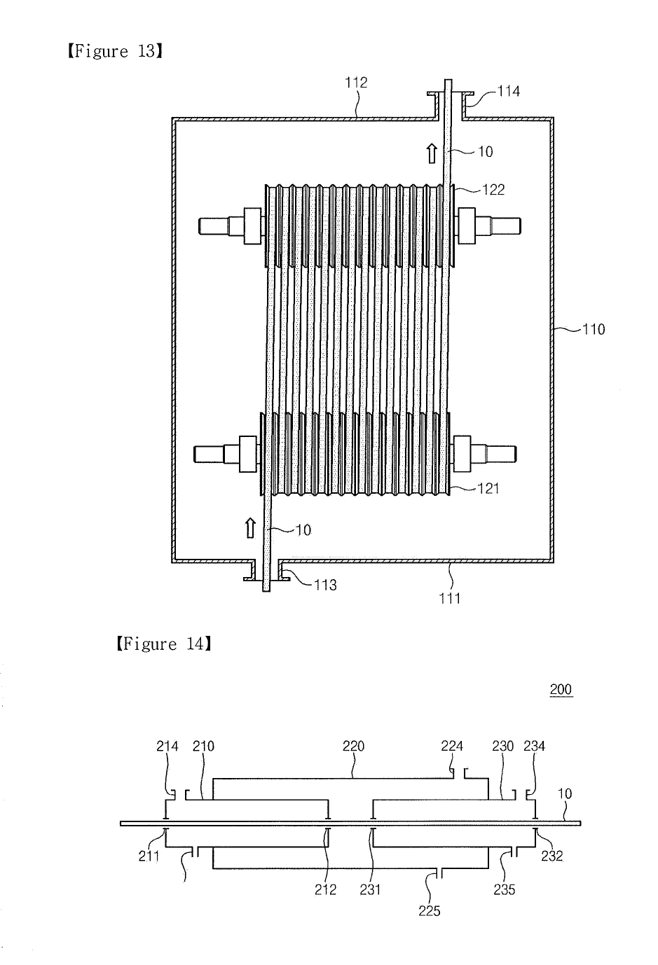

FIG. 13 is a top plan view of a reel-to-reel device according to the inventive concept. Referring to FIGS. 12 and 13, a reel-to-reel device 120 includes a first reel member 121 and a second reel member 122 that are spaced and face each other. The deposit ion member 130 is disposed below the substrate between the first reel member 121 and the second reel member 122. The first reel member 121 and the second reel member 122 multiturn the substrate 10 in a region where a superconducting precursor film is deposited. That is, the substrate 10 is turned at the first reel member 121 and the first second reel member 122 while travel ing back and forth between the first reel member 121 and the second reel member 122. The first reel member 121 is provided adjacent to a first sidewall 111 of the process chamber 110, and the second reel member 122 is provided adjacent to a second sidewall 112 of the process chamber 110. The first reel member 121 and the second reel member 122 may have the same configuration. The first reel member 121 and the second reel member 122 may extend in a direction intersecting the back-and-forth direction of the substrate 10.

The first reel member 121 and the second reel member 122 include reels disposed in the extending direction of the first reel member 121 and the second reel member 122 to be coupled to each other, respectively. The substrate 10 is turned at the respective reels. When viewed from the top, the second reel member 122 is slightly misaligned with the first reel member 121 to multiturn the substrate 10. The substrate 10 moves in the extending direction of the first reel member 121 and the second reel member 122 while traveling back and forth between the first reel member 121 and the second reel member 122.

FIG. 14 schematically illustrates a heat treatment unit 200 in an apparatus for forming a superconducting body according to the inventive concept. Referring to FIG. 14, the heat treatment unit 200 may include a first container 210, a second container 220, and a third container 230 that are disposed sequentially adjacent to each other to allow a substrate 10 to pass therethrough. The first container 210 and the third container 230 are spaced apart from each other. A center portion of the second container 220 may correspond to a space where the first container 210 and the third container 230 are spaced apart from each other. The second container 220 is configured to surround a portion of the first container 210 and a portion of the third container 230. Each of the first, second, and third containers 210, 220, and 230 may be formed of cylindrical quartz pipes. The first container 210 may be connected to a withdrawal part 114 of a thin film deposition unit 100. The first and third containers 210 and 230 may include introduction and withdrawal parts 211, 212, 231, and 232 disposed at their both ends to allow the substrate 10 to pass therethrough. The substrate 10 is introduced to the first introduction part 211 of the first container 2410 and withdrawn to the first withdrawal part 212 of the first container 210. After passing through a center portion of the second container 220, the substrate 10 may be introduced to the second introduction part 231 of the third container 230 and withdrawn to the second withdrawal part 232 of the third container 230. The first container 210, the second container 220, and the third container 230 may independently maintain vacuum. For achieving this, the first container 210, the second container 220, and the third container 230 may include separate pumping ports 214, 224, and 234 and oxygen supply parts (not shown), respectively. Oxygen may be supplied through the oxygen supply parts to independently adjust oxygen partial pressures in the first container 210, the second container 220, and the third container 230. For example, the oxygen partial pressure in the first container 210 may be lower than that in the third container 230, and the oxygen partial pressure in the second container 220 may be maintained between the partial pressure in the second container 220 and the partial pressure in the third container 230. The oxygen partial pressure in the second container 220 may increase as it goes from a portion adjacent to the first container 210 to a portion adjacent to the third container 230.

The first container 210, the second container 220, and the third container 230 are provided into a furnace surrounding the same. A spaced portion of the first container 210 and the third container 230 may be disposed around the center of the furnace. Thus, a temperature at the center portion of the second container 220 may be maintained higher than temperatures in the first container 210 and the third container 230. The temperatures in the first container 210 and the third container 230 may decrease as it goes away from the center portion of the second container 220.

A heat treatment procedure according to the foregoing embodiments will now be described with the heat treatment unit 200 in FIG. 14. A path I may be carried out while the substrate 10 passes through the first container 210 of the heat treatment unit 200. The first container 210 may have a relatively low oxygen partial pressure (e.g., 1×0⁻⁶˜1×10⁻³ Torr). A temperature in the first container 210 may increase from the first introduction part 211 to reach about 800 degrees centigrade at the first withdrawal part 212. A path II is carried out while the substrate 10 passes through the center portion of the second container 220 of the heat treatment unit 200. The second container 220 may have an oxygen partial pressure of, for example, 1×10⁻²˜10⁻¹ Torr. The oxygen partial pressure in the second container 220 may increase as it goes from a portion adjacent to the first container 210 to a portion adjacent to the third container 230. A temperature at the center portion of the second container 220 may be about 850 degrees centigrade or higher. A path III may be carried out while the substrate 10 passes through the third container 230 of the heat treatment unit 200. The third container 230 may have an oxygen partial pressure of, for example, 5×10⁻²˜3×10⁻¹ Torr. A temperature in the third container 230 may decrease from about 850 degrees centigrade of the second introduction part 221 as it goes to the second withdrawal part 222. A cooling rate may be 1° C./hr or higher (about 5° C./hr).

In the foregoing embodiment, it has been described that the thin film deposition unit 100, the heat treatment unit 200, and the substrate feeding/collecting unit 300 are constructed in a single body. However, the inventive concept is not limited thereto.

In one embodiment, a substrate feeding/collecting unit 300 may be separately provided to a thin film deposition unit 100 and the heat treatment unit 200, respectively. First, a substrate feeding/collecting unit winding a substrate is mounted on the thin film deposition unit 100. In the thin film deposition unit 100, a superconducting precursor film is formed on a substrate. The thin film deposition unit 100 may have a different configuration than the foregoing example. For example, the thin film deposition unit 100 may be a unit for metal organic deposition (MOD). Next, a line material feeding/collecting unit winding the substrate where the superconducting precursor film is formed is separated from the thin film deposition unit 100. The substrate where the superconducting precursor film is formed may be mounted on the heat treatment unit 200. Thereafter, the substrate where the superconducting precursor film is formed may be subjected to heat treatment.

In another embodiment, a substrate may be not a wire type but a large-area plate type. In this case, a substrate feeding/collecting unit may have a different configuration than the foregoing example. A substrate is provided to a thin film deposition unit, and a superconducting precursor film is formed on the substrate. The substrate where the superconducting precursor film is provided to a device capable of performing the foregoing heat treatment steps to be subjected to a heat treatment.

While the inventive concept has been particularly shown and described with reference to exemplary embodiments thereof, it will be apparent to those of ordinary skill in the art that various changes in form and detail may be made therein without departing from the spirit and scope of the inventive concept as defined by the following claims.

### INDUSTRIAL APPLICABILITY

The inventive concept may be used in fields such as a magnetic resonance imaging (MRI), a superconducting magnetic levitation train, and a superconducting electromagnetic propulsion ship.

1. A method of forming a superconducting body, comprising:
providing rare-earth element-copper-barium oxide including a rare-earth element, barium, and copper; and
performing a heat treatment on the rare-earth element-copper-barium oxide to form a superconductor containing grains of rare-earth oxide distributed therein,
wherein performing the heat treatment comprises:
a first heat treatment step in which a temperature increases such that the rare-earth element-copper-barium oxide has a liquid phase containing the rare-earth oxide; and
a second heat treatment step in which a temperature and/or an oxygen pressure are changed from that of the first heat treatment step to form a single-crystalline rare-earth element-copper-barium oxide.

2. The method as set forth in claim 1, wherein the single-crystalline rare-earth element-barium-copper oxide is grown from the rare-earth oxide.

3. The method as set forth in claim 2, wherein an oxygen partial pressure in the first heat treatment step is 10⁻⁶˜10⁻³ Torr, and an oxygen partial pressure in the second heat treatment step is 10⁻³˜10⁻¹ Torr.

4. The method as set forth in claim 2, wherein a grain of the rare-earth oxide has a size less than 1 micrometer.

5. The method as set forth in claim 1, wherein the rare-earth element-copper-barium oxide is formed on a substrate, and
wherein the substrate includes a metal having a textured structure or an oxide buffer layer having a textured structure on a metal substrate.

6. Crystalline rare-earth-barium-copper oxide comprising grains of rare-earth oxide and grains of barium-cooper oxide which are distributed therein.

7. The crystalline rare-earth-barium-copper oxide as set forth in claim 6, further comprising:
grains of copper oxide distributed in the crystalline rare-earth-barium-copper oxide.

8. The crystalline rare-earth-barium-copper oxide as set forth in claim 6, wherein each of the grains of rare-earth oxide has a size less than 1 micrometer.

9. The crystalline rare-earth-barium-copper oxide as set forth in claim 6, wherein each of the grains of rare-earth oxide has an elongated shape.

10. A superconducting body comprising:
a substrate;
the crystalline rare-earth-barium-copper oxide as set forth in claim 6, formed on the substrate; and
barium-copper oxides formed on a top surface of the crystalline rare-earth element-barium-copper oxide.

11. The superconducting body as set forth in claim 10, wherein the substrate includes a metal having a textured structure or an oxide buffer layer having a textured structure on a metal substrate.
